(19) United States
(12) Patent Application Publication
(10) Pub. No.: US 2014/0042281 A1
(43) Pub. Date: Feb. 13, 2014

(54) Apparatus To Provide Temporary Support To A Portable Device

(71) Applicants: Jason Mick, Converse, TX (US); Joe Wiese, Universal City, TX (US); Joel Wineland, Garden Ridge, TX (US)

(72) Inventors: Jason Mick, Converse, TX (US); Joe Wiese, Universal City, TX (US); Joel Wineland, Garden Ridge, TX (US)

(21) Appl. No.: 13/569,451

(22) Filed: Aug. 8, 2012

(51) Int. Cl. H05K 7/00; F16M 13/02

(52) U.S. Cl. 248/224.8

(57) ABSTRACT

According to one aspect, the present invention includes a support apparatus having a support hub with a chamber to house a plurality of support arms and a coupling member to adapt the support arms about an axis. The support arms may extend from the support hub, and at least one of the support arms can be movable about the axis. One or more of these support arms are insertable within a space between a first rack device and a second rack device of a rack to enable the support apparatus to be a mounting location for a peripheral device.

### BACKGROUND

When working in certain environments, such as within a data center environment, a worker such as a technician, IT personnel or so forth may desire to use various portable devices while located at a particular piece of data center equipment. This equipment may be a rack that includes various rack-mounted devices such as servers, storage devices or so forth. It is often difficult to support such portable devices. For example, a user may seek to use a portable computing device such as a laptop computer, tablet computer or so forth. However, there generally is no suitable place for the user to support the computing device. This is especially so, as the user will often try to use the computing device with one hand while supporting it with the other hand. Clearly, this is not a desirable situation.

Furthermore, whether the portable device is a computing device, a storage or other device, e.g., to provide data to or receive data from a piece of equipment in a rack, again the issue of support is not adequately addressed.

### SUMMARY OF THE INVENTION

According to one aspect, the present invention includes a support apparatus having a support hub with a chamber to house a plurality of support arms and a coupling member to adapt the support arms about an axis. The support arms may extend from the support hub, and at least one of the support arms can be movable about the axis. One or more of these support arms are insertable within a space between a first rack device and a second rack device of a rack to enable the support apparatus to be a mounting location for a peripheral device.

In a given implementation, the support hub has a support structure to which the peripheral device can be coupled. Also, an extension rod having a proximal end coupled to the support structure may be provided to enable the peripheral device is to couple to a distal end of the extension rod. Also, each of the support arms may include a detent mechanism on a proximal end and a plate member on a distal end, so that the detent mechanism can mate with a corresponding detent mechanism of another support arm to enable the support arms to remain in a locked position with respect to each other.

Another aspect of the present invention is directed to a support device that is formed of a conductive material. This device may have a core and a coil adapted around the core, where the coil is to receive a signal via one end of the coil and to couple to a ground connection via another end of the coil. When the coil is powered by the signal and coupled to the ground connection, the support device is powered as an electromagnet that is adapted to be electromagnetically affixed to a metal enclosure. The support device can include a support member to support a peripheral device when powered.

As one example, the support device can be powered via a universal serial bus (USB) connection to the peripheral device or to a device in the metal enclosure, which may be a rack system of a data center including a plurality of rack-supported devices.

Optionally, an extension rod having a proximal end can couple to the support device to enable a portable computing device to couple to a distal end of the extension rod. In addition, a second support device coupled to the distal end of the extension rod can support the portable computing device, which may be a tablet computer.

A still further aspect is directed to an arrangement having an electromagnet to receive a signal through a coil configured around a core that when powered is adapted to be electromagnetically affixed to a metal structure. The coil is coupled to receive the signal via a USB connection with signal and ground connections, but not including a data connection. In turn, a first support member is adapted to the electromagnet, with an extension rod having a proximal end coupled to the first support member, and a second support member coupled to the distal end of the extension rod. With this arrangement, the second support member can support a portable computing device in relation to the metal structure.

### BRIEF DESCRIPTION OF THE DRAWINGS

FIG. 1 is an illustration of a peripheral mounting device in accordance with an embodiment of the present invention.

FIG. 2 is a cross section view of a mounting device in accordance with an embodiment of the present invention.

FIG. 3 is a block diagram of connection of a mounting device to an example peripheral device.

FIG. 4 shows an embodiment in which a support rod couples a mounting device to a peripheral device in accordance with an embodiment of the present invention.

FIG. 5 is a block diagram of another example of a mounting device in accordance with an embodiment of the present invention.

FIG. 6 is a block diagram of an electromagnet-based support structure in accordance with an embodiment of the present invention.

FIG. 7 is a block diagram of a coupling of an electromagnet support in accordance with an embodiment to a rack.

FIG. 8 is an illustration of another support in accordance with an embodiment of the present invention.

### DETAILED DESCRIPTION

In various embodiments, different types of support devices can be provided that enable a user to mount and adapt the support device to a piece of equipment such as a data center rack in a temporary manner. Then a user can adapt a peripheral or other portable device to this support device, either directly or via an intermediate structure such as an extension device (to which the device to be supported can be directly connected or connected through another supporting device). Different embodiments will be described herein, however understand the scope of the present invention is not limited to the illustrated embodiments and various modifications of the support devices described herein are possible.

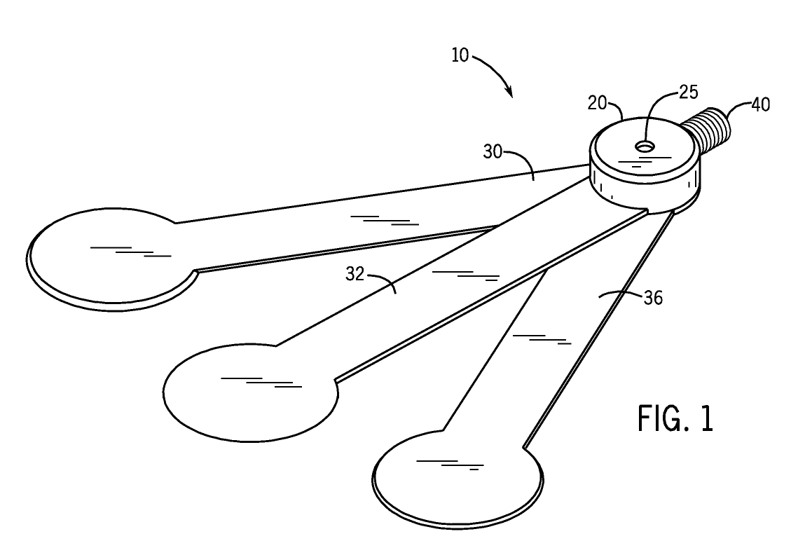

Referring now to FIG. 1, shown is an illustration of a peripheral mounting device in accordance with an embodiment of the present invention. As shown in FIG. 1, device 10 can be used to adapt one or more devices such as peripheral devices to a rack system such as the familiar 19-inch server rack assembly.

In general, mounting device 10 can couple directly or indirectly to a peripheral device (not shown in FIG. 1) while adapted to, e.g., temporary locked within a rack (also not shown for ease of illustration in FIG. 1), as will be described herein. As seen in FIG. 1, mounting device 10 includes a hub portion 20 that forms a housing from which a plurality of support arms 30, 32 and 36 extend. In an embodiment, these support arms can extend from a central axis 25, e.g., through which a bolt or other coupling member can be adapted.

As further seen in FIG. 1, a support structure 40 may extend from hub portion 20. In the embodiment shown, support structure 40 may be a threaded adapter that can receive a corresponding threaded portion of a peripheral device that is to be coupled to and supported by device 10. In an embodiment, support structure 40 may be a mounting screw to enable the user to attach multiple different types of mounts. In other implementations, instead of directly coupling a peripheral device to mounting device 10, a separate support structure (not shown in FIG. 1) can be configured between mounting device 10 and the peripheral device. For example, an extension rod can be threaded onto support structure 40 via a first threading portion on one end of the rod, and a peripheral device can be mounted to the second end of the rod, either by another threaded adapter or in another manner.

To provide safe support of mounting device 10 (and a peripheral device coupled to it) when used in connection with a mounting location such as an open space within a rack or other piece of equipment such as may be present in a data center environment, support arms or other support member can be engaged. More specifically, one or more of support arms 30, 32 and 36 may be adapted within a space between different rack-mounted devices present within a rack. In general, the support arms may act as scissor-like members to be installed in the space between servers. Typical rack mount servers have approximately ⅛″ space in between each server to allow for the servers to move without touching the server above or below it. Mounting device 10 can utilize this empty space as temporary mounting location. The device resembles a scissor. In an embodiment the distal portions of support arms 30 and 36 may be round plates that are about 3/32″ thick extending from the arms. The arms themselves may have a length of between approximately 8″ and 10″ in an embodiment.

To mount the device, at least two plates are moved over the tops of each other (in a substantially vertical orientation) like closing a scissor, which fills the void in between the two rack-mounted devices and holds the device tight. Note that hub portion 20 can provide for expansion to the device to allow multiple plates to be installed, to allow the device to be installed in a larger gap, e.g., larger than ⅛″.

When the user seek to lock the mounting device in place, he inserts it in between the two servers and moves the arms so the plates at least partially overlap each other in a substantially vertical configuration to lock it in place.

Embodiments allow a portable computing device like a laptop computer to be attached to the rack. As well this device is also intended to allow the connection of multiple devices like portable network switches, hard disk drives, etc, as a temporary, rather than a permanent mounting solution.

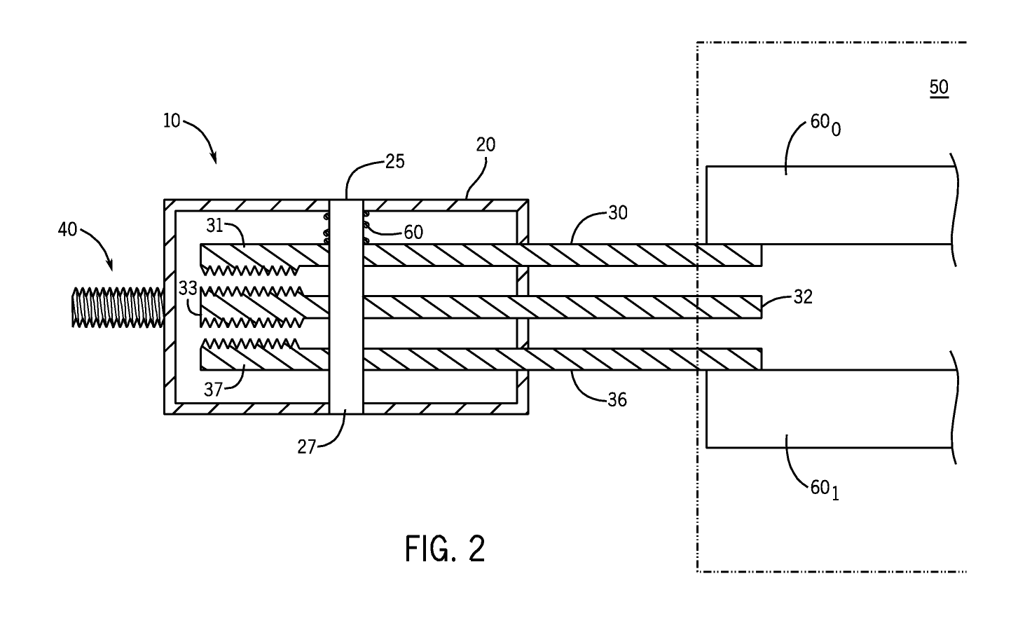

Referring now to FIG. 2, shown is a cross section view of a mounting device in accordance with an embodiment of the present invention and its adaptation within a rack. As seen in FIG. 2, device 10 includes multiple support arms 30, 32, and 36, each of which are configured about a central axis 25 that may receive a bolt, screw, or other coupling member to thus maintain the support arms within hub portion 20. As further seen, to provide for an appropriate amount of tension between these support arms, a spring 60 may be coupled between a top portion of hub portion 10 and an upper most support arm 30. Furthermore, to enable the support arms to freely move with respect to each other, and then be locked into place with respect to each other, each of the support arms can include a retention portion 31, 33, and 37. In various embodiments, these retention portions can be implemented by teeth integrated on the support arms or adapted thereto. Other retention members such as a given ratcheting mechanism cam member, or other detent mechanism can be used in different embodiments.

Note that in many embodiments, central support arm 32 may be maintained in a fixed state, and upper and lower (peripheral) support arms 30 and 36 may rotate with respect to support arm 32. In this way, depending on an actual width of an opening into which the mounting device is to be adapted, one or both of the support arms can be located in a substantially symmetrical vertical orientation with central support arm 32 to enable locking into a particular sized opening. Furthermore, note that in some embodiments, as shown for example in FIG. 1, the moveable support arms 30 and 36 may have beveled edges on the distal plate ends to enable more refined adaptation both to central support arm 32 as well as to an opening into which they are provided.

Also shown in FIG. 2 is a rack 50 which may be a server rack, storage rack, load balancer rack, switch rack or another such rack that includes various components that can be configured within the rack. As seen in FIG. 2, two rack-mounted devices 60₀ and 60₁ are present. In typical racks, there is some amount of space between two rack-mounted devices, which for the example shown each can be a server chassis that includes one or more servers, generally including at least one processor, memory, mass storage, network devices and so forth. To enable locking of mounting device 10 within this opening, a user can configure these support arms (at least 2 and often times 3) to be at least substantially vertically oriented so that a desired width of the opening is filled with the support arms (more particularly the distal plate ends of the support arms) to thus lock mounting device 10 into rack 50.

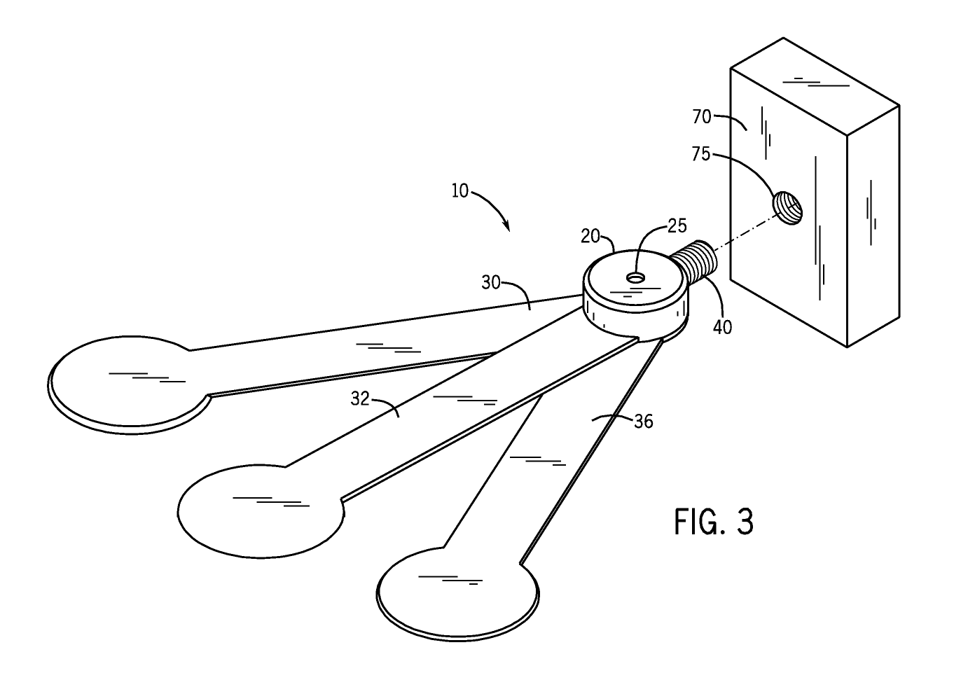

As discussed above, different types of devices can be adapted to a mounting device. Referring now to FIG. 3, shown is a block diagram of connection of a mounting device to an example peripheral device. Specifically shown in FIG. 3, mounting device 10 can couple to a portable disk drive 70 via a thread portion 75 configured within the enclosure of disk drive 70 that can engage with support structure 40 of the mounting device.

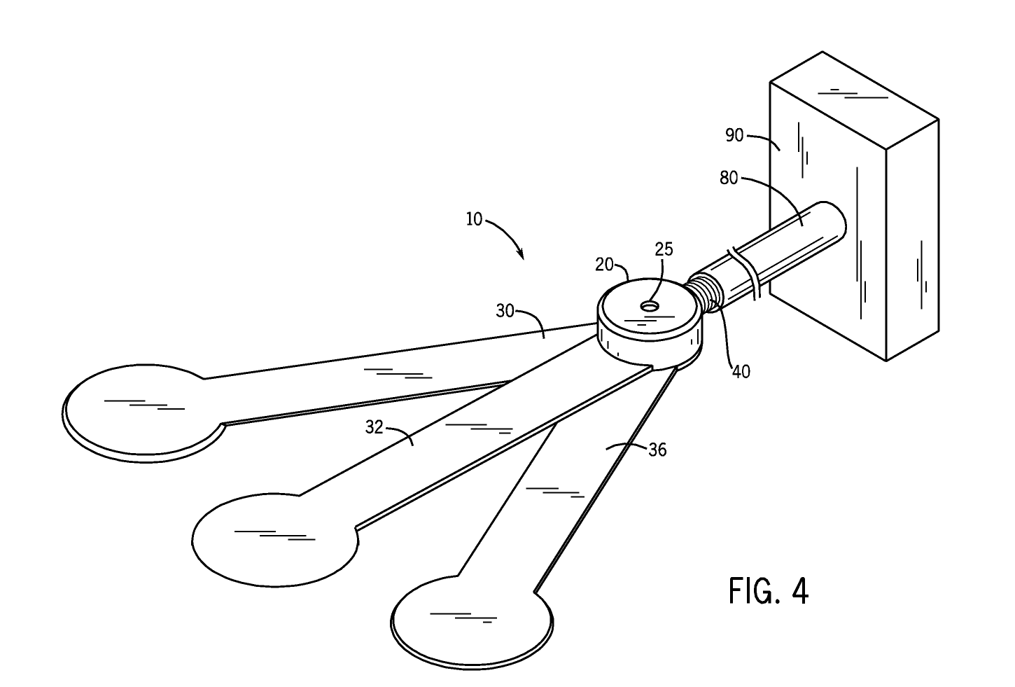

Other implementations are possible. FIG. 4 shows an embodiment in which an extension device such as a support rod 80 may couple to mounting device 10 and in turn a peripheral device 90 such as a network device can couple to the distal end of support rod 80. Again, the connections can be by way of threaded members, although other adaptation mechanisms are possible.

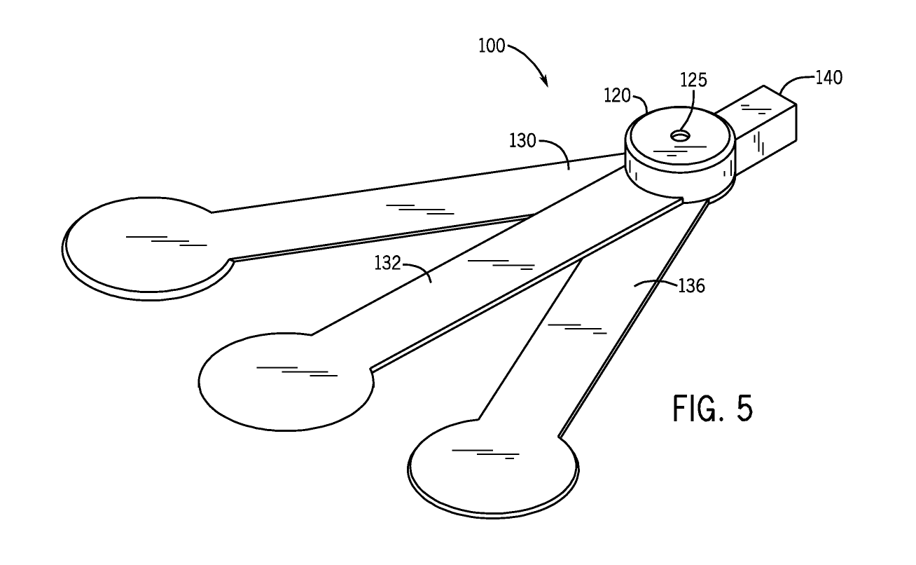

FIG. 5 is a block diagram of yet another example of a mounting device. In general, mounting device 100 may be configured the same as mounting device 10 of FIG. 1. However, instead of a threaded adapter as a support structure 40, mounting device 100 includes a support protrusion 140 which can act to slideably receive a peripheral or other support member that can thus slide about this protrusion 140. Although shown with these particular examples above, understand that other types of mechanisms to adapt a mounting device, both to a rack or other data center equipment and to a peripheral device are contemplated.

Another manner of adapting peripheral equipment such as portable devices to a data center rack or other structure may be by way of an electromagnetic support member that can be magnetically attached to the rack and which further supports the peripheral device.

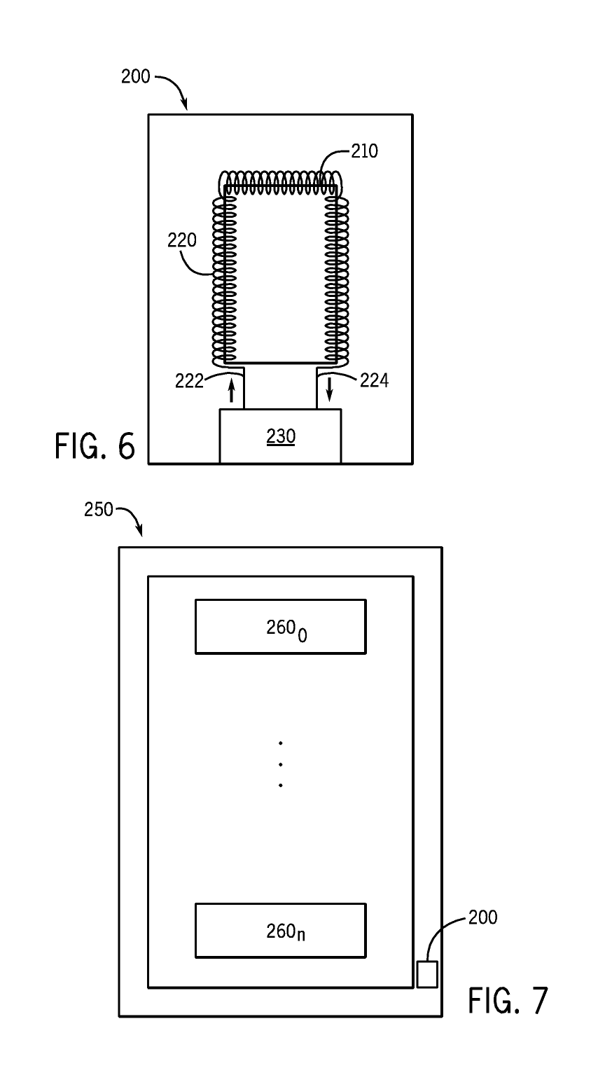

Referring now to FIG. 6, shown is an example of an electromagnet-based support structure in accordance with an embodiment of the present invention. As shown in FIG. 6, support device 200 may be a relatively small support structure, generally of rectangular shape, that can be configured to adapt to a side portion of a rack structure and be magnetically affixed thereto and enable one or more peripheral devices to be supported by a front side of the support structure. In an embodiment, the electromagnet within the support device may have a width on the order of up to approximately 1.75 inches, and may have a length of between approximately 2 to 4 inches, and a thickness of between approximately 1 to 1.5 inches. In another embodiment, the electromagnet may be configured as a round magnet. In an embodiment the magnet may have a diameter on the order of up to approximately 1.75 inches and may have a thickness on the order of up to approximately 3 inches to provide the requisite holding force. In an embodiment, a round electromagnet can be commercially obtained from APW Co., Rockaway N.J., and having a part number EM175-6-122. Note that a modification may be made to a commercially available magnet to enable it to operate with a voltage of 5V provided via a USB connection, instead of a rated 6V level. For example, a number of the windings may be reduced, or a wire gauge can be changed. To realize the support device using such magnet, a mounting mechanism can be configured around or through the center of the magnet.

Specifically, the embodiment of FIG. 6 contemplates a powered electromagnet that may be powered by a universal signal bus (USB)-based connection. The power can be provided from a peripheral device to be coupled to the support, or it can be provided via a rack-mounted device within the rack. As shown in FIG. 2, support structure 200 includes a central core 210 which may be an iron core, around which a coil 220 such as a copper coil may be adapted. In turn, the structure 200 itself may also be made of a metal material. Not shown in FIG. 6 is an adapter of the support structure, such as a threaded adapter to which a peripheral or other portable device can be mounted.

Thus an electromagnet is formed that when powered by receipt of an appropriate voltage signal via an input conductor 222 (which may be of the coil or coupled to it) and connection of a ground conductor 224 (which may be of the coil or coupled to it) provides an active electromagnet that can thus electromagnetically attach to a rack or other piece of conductive (e.g., metal) equipment.

As further seen in FIG. 2, the power and ground signals may be made via a USB port 230. Although a conventional USB connection of various types may be made (e.g., USB 1.0, USB 2.0, 3.0, and of a Type A, Type B, Mini-A, Mini-B, Micro-A, or Micro-B connector), note that only power and ground connections are used as there is no data transfer via this USB port. In an embodiment, device 200 may act as a USB-powered electromagnet that requires around 500 milliamperes at 5 volts to supply approximately 6-8 pounds of holding force when attached to a 1/16″ inch metal plate. Of course embodiments can be powered in other manners, and are not limited to the USB port described herein.

Referring now to FIG. 7, shown is a block diagram of a coupling of an electromagnet support in accordance with an embodiment to a rack. As seen, a rack 250 includes various rack-mounted devices 260₀-260ₙ (which as discussed above can be servers, storage devices or so forth). To enable peripheral devices (such as those described above) to be supported in close location to this rack, electromagnet support 200 can be affixed (at least temporarily) to a side portion of rack 250. Then one or more peripheral devices can be coupled to this support e.g., by a threaded or other connection.

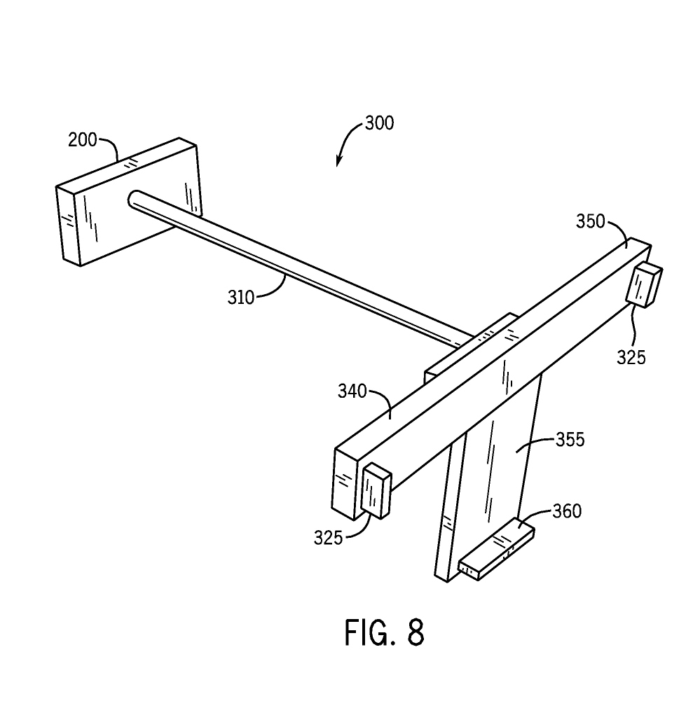

Referring now to FIG. 8, shown is an illustration of another support in accordance with an embodiment of the present invention. As shown in FIG. 8, system 300 includes an electromagnet-powered support device 200 which may be in accordance with device 200 described above in FIG. 6. This support device can be coupled to an extension rod 310 which may be made out of a flexible steel tube that is common design for microphone booms. Rod 310 may couple to a second support device 350 which may be used to provide an adjustable securing mechanism for a portable device such as a laptop, tablet computer, smart phone or other portable computing device. As seen, second support device 350 can include a horizontal support member 340 to which a pair of adjustable securing mechanisms 325 may be provided which can be movably configured to correspond to a width of a computing device. Extending downwardly from horizontal support member 340 may be vertical support member 355 which may have at its terminal end a support mount 360, on which a base of a laptop or other portable computer can be adapted.

Adjustable mount 350 can accommodate multiple different sizes of devices. In other embodiments, device 200 may include a support member such as a threaded adapter that can mate with a complementary adapter of the portable device. Thus using support system 300, a powered electromagnet can be created (and which can be powered by the portable device itself or from a voltage source available to a piece of equipment to which support device 200 adapts). Inside extension rod 310 is a USB power cable that then breaks out to a standard USB connection at a distal end. where the laptop or other portable device is mounted. Or the power cable can be avoided where power is to be received directly from a rack-mounted device of a rack (not shown in FIG. 8). In other embodiments, the adjustable mount and the extension rod can be adapted to a mounting device such as that of FIG. 1.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An apparatus comprising:
a support hub having a chamber to house a plurality of support arms, the support hub further having a coupling member to adapt the support arms about an axis; and
the support arms extending from the support hub, at least one of the support arms movable about the axis, wherein at least some of the support arms are insertable within a space between a first rack device and a second rack device of a rack to enable the apparatus to be a mounting location for a peripheral device.

2. The apparatus of claim 1, wherein the support hub further comprises a support structure to which the peripheral device can be coupled.

3. The apparatus of claim 2, further comprising an extension rod having a proximal end coupled to the support structure and wherein the peripheral device is to couple to a distal end of the extension rod.

4. The apparatus of claim 1, further comprising a spring adapted about the axis to provide tension to the plurality of support arms.

5. The apparatus of claim 1, wherein each of the support arms includes a detent mechanism on a proximal end and a plate member on a distal end, the detent mechanism to mate with a corresponding detent mechanism of another support arm to enable the support arms to remain in a locked position with respect to each other.

6. The apparatus of claim 5, wherein the plate member of at least some of the support arms are beveled.

7. The apparatus of claim 1, wherein the plurality of support arms comprise a first peripheral support arm, a second peripheral support arm, and a central support arm located between the first and second peripheral support arms, wherein the central support arm is affixed about the axis and the first and second peripheral support arms are movable about the axis.

8. The apparatus of claim 7, wherein the first peripheral support arm and the central support arm are to be engaged in substantial vertical alignment to adapt the apparatus within a first space having a first dimension.

9. The apparatus of claim 8, wherein the first peripheral support arm, the second peripheral support arm, and the central support arm are to be engaged in substantial vertical alignment to adapt the apparatus within a second space having a second dimension greater than the first dimension.

10. An apparatus comprising:
a support device of a conductive material and having a core and a coil adapted around the core, the coil to receive a signal via a first end of the coil and to couple to a ground connection via a second end of the coil, wherein when the coil is powered by the signal and coupled to the ground connection, the support device is powered as an electromagnet that is adapted to be electromagnetically affixed to a metal enclosure.

11. The apparatus of claim 10, wherein the support device includes a support member to support a peripheral device when the support device is powered as an electromagnet.

12. The apparatus of claim 11, when the support device is powered via a universal serial bus (USB) connection to the peripheral device to provide the signal.

13. The apparatus of claim 10, wherein the support device is powered via a universal serial bus (USB) connection to a device in the metal enclosure to provide the signal, the metal enclosure corresponding to a rack system of a data center including a plurality of rack-supported devices.

14. The apparatus of claim 13, when the USB connection includes a connector for the signal and a connector for the ground connection, and not including data connectors.

15. The apparatus of claim 11, further comprising an extension rod having a proximal end to couple to the support device and wherein a portable computing device is to couple to a distal end of the extension rod.

16. The apparatus of claim 15, further comprising a second support device coupled to the distal end of the extension rod, wherein the second support device is to support the portable computing device.

17. The apparatus of claim 16, wherein the portable computing device comprises a tablet computer.

18. An apparatus comprising:
an electromagnet to receive a signal through a coil configured around a core that when powered is adapted to be electromagnetically affixed to a metal structure, wherein the coil is coupled to receive the signal via a universal serial bus (USB) connection that includes a signal connection and a ground connection and not including a data connection;
a first support member adapted to the electromagnet;
an extension rod having a proximal end coupled to the first support member; and
a second support member coupled to the distal end of the extension rod, wherein the second support member is to support a portable computing device in relation to the metal structure.

19. The apparatus of claim 18, wherein the electromagnet is to be powered by the portable computing device via the USB connection.

20. The apparatus of claim 18, wherein the electromagnet is to be powered by a device in the metal structure via the USB connection, the metal structure corresponding to a rack system of a data center including a plurality of rack-supported device.
